(19) United States
(12) Patent Application Publication
(10) Pub. No.: US 2026/0179681 A1
(43) Pub. Date: Jun. 25, 2026

(54) Bitline Precharge Circuitry and Methods

(71) Applicant: Arm Limited, Cambridge (GB)

(72) Inventors: Rahul Mathur, Austin, TX (US); Andy Wangkun Chen, Austin, TX (US); Nikhil Gutti Pyidi Venkata Yuva, Austin, TX (US); Yew Keong Chong, Austin, TX (US)

(21) Appl. No.: 19/000,311

(22) Filed: Dec. 23, 2024

(51) Int. Cl. G11C 11/419; G11C 11/412

(52) U.S. Cl. CPC G11C 11/419; G11C 11/412

(57) ABSTRACT

A circuit includes first and second logic gates, where the first logic gate is configured to output a bitline precharge signal based on a global bitline precharge signal and an output of the second logic gate, and the output of the second logic gate is based on at least a sense amplifier precharge signal and a control signal. Also, the circuit is configured to control a precharge of one or more bitcells based on enabling or disabling the bitline precharge signal. A method includes: detecting, by a circuit, one GTP pulse or two GTP pulses per unit cycle, where the one GTP pulse corresponds to either a read operation or a write operation, and the two GTP pulses correspond to both the read operation and the write operation.

### I. FIELD

The present disclosure is generally related to systems, methods, and devices for bitline precharge circuitry.

### II. DESCRIPTION OF RELATED ART

Graphics processing units (GPUs) are widely used in computing systems for tasks requiring high parallelism and computational throughput, such as graphics rendering, artificial intelligence, and scientific computation. One component within a GPU’s architecture is the execution engine general-purpose register file (EE-GPRF), which stores data and instructions critical to the GPU’s operation. However, the dynamic power consumption of the EE-GPRF contributes significantly to the overall power usage of the GPU, accounting for approximately 10% of the GPU's total dynamic power consumption. Given the growing demand for power-efficient GPUs, there is a pressing need to reduce dynamic power consumption, particularly, for example, in EE-GPRF memory.

### III. BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1 is a diagram of an example circuit in accordance with various implementations described herein.

FIGS. 2A-2D are example timing diagrams in accordance with various implementations described herein.

FIG. 3 is an operational flow diagram in accordance with various implementations described herein.

FIG. 4 is an operational method in accordance with various implementations described herein.

FIG. 5 is an operational method in accordance with various implementations described herein.

FIG. 6 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### IV. DETAILED DESCRIPTION

Implementations of the present disclosure are described below with reference to the drawings. In the description, common features are designated by common reference numbers throughout the drawings.

In one implementation, the present disclosure describes a circuit to selectively control the enabling or disabling of a bitline precharge signal. The circuit includes first and second logic gates, where the first logic gate is configured to output a bitline precharge signal based on a global bitline precharge signal and an output of the second logic gate, and the output of the second logic gate is based on at least a sense amplifier precharge signal and a control signal. Also, the circuit is configured to control a precharge of one or more bitcells based on enabling or disabling the bitline precharge signal.

In another implementation, the present disclosure describes a method of selective bitline precharge. The method includes: detecting, by a circuit, one GTP pulse or two GTP pulses per unit cycle, where the one GTP pulse corresponds to either a read operation or a write operation, and the two GTP pulses correspond to both the read operation and the write operation; and 2) in response to the detection of one GTP pulse, enablingthe bitline precharge signal after the one GTP pulse.

In another implementation, the present disclosure describes a method to reduce dynamic power for read-write cycle. The method includes: 1) receiving, by a circuit in a clock cycle, first and second GTP pulses; 2) in response to a write mask being active, enabling, by the circuit, the bitline precharge signal for a duration between a read operation and a write operation; and 3) in response to a write mask being inactive, disabling, by the circuit, the bitline precharge signal for a duration corresponding to both the read operation and the write operation.

Traditionally, EE-GPRF is implemented using single-port (SP) static random-access memory (SRAM) with column multiplexing (Col Mux1) and write masking (Write-Mask ON) capabilities. While this design is effective for storing and retrieving data, it consumes considerable dynamic power, especially in high-performance GPUs. Recently, there has been interest in using pseudo-two-port (p-2P) memory in place of traditional single-port SRAM, as p-2P memory can provide similar access benefits while potentially lowering dynamic power usage. However, despite its potential, p-2P memory requires additional optimizations to fully achieve these power savings.

A significant portion of the dynamic power consumed by EE-GPRF memory arises from bit-line (BL) precharging operations. For example, in pseudo-dual-port SRAM, bit-line precharging occurs twice within each clock cycle: once after a read operation and again after a write operation. While these dual precharge cycles are essential for maintaining stable data access, they contribute heavily to power consumption. One potential optimization involves skipping the first bit-line precharge following a read operation to save power. However, this approach presents a challenge when write-masked bits are involved. Skipping the initial precharge after a read operation for write-masked bits can lead to read disturb errors during subsequent write operations, threatening data integrity and potentially leading to functional errors in GPU processing.

Advantageously, inventive aspects of the present invention are directed to a memory architecture that enables the dynamic power savings associated with skipping certain bit-line precharge operations while preserving data stability and preventing read disturb failures. Schemes and techniques, as described herein, address the need to provide a control mechanism that selectively skips the first bit-line precharge after a read operation based on runtime conditions. According to certain inventive aspects, a local sense amplifier precharge signal may be introduced with the capacity to “block” a global bit-line precharge signal during a first precharge cycle, thereby achieving power savings without sacrificing reliability. Moreover, inventive schemes and techniques described herein utilize run-time write enable (WEN) information to detect write-masked bits in real-time to disable the skip-precharge feature when needed to prevent read disturb issues. Additionally, inventive aspects described herein advantageously do not utilize a YW global signal (e.g., a write control signal) and/or its associated logic, further simplifying the memory’s control circuitry, reducing signal congestion, and enhancing efficiency. Advantageously, by reducing the dynamic power consumption of EE-GPRF memory, the inventive solution described herein meets the growing demand for power-efficient GPU architectures, providing a critical advancement in the design of register files for GPUs and other high-performance computing systems.

Certain definitions have been provided herein for reference. An Execution Engine-General Purpose Register File (EE-GPRF) is a specialized memory structure in computing systems, particularly in Graphics Processing Units (GPUs), designed to store data that is actively used by the GPU's execution engine. It serves as a high-speed storage unit that temporarily holds operands, intermediate results, and other essential data required for executing instructions efficiently. The EE-GPRF is a central component of a GPU's architecture, designed to provide fast, efficient, and reliable storage for the execution engine’s data needs while balancing the challenges of power and performance.

Pseudo-Two-Port (p-2P) Memory is a memory architecture designed to emulate the functionality of true dual-port memory by enabling one read and one write operation within a single clock cycle using time-multiplexed access, while sharing internal resources such as bit lines and word lines. This approach reduces the area and power consumption compared to true dual-port memory, making it more efficient for high-performance applications like GPUs and AI accelerators. p-2P memory utilizes sophisticated control logic to manage resource arbitration and ensure data integrity, while employing techniques such as bit-line precharging after read and write operations to maintain operational stability. Advantageously, according to inventive aspects as described herein, optimizations (e.g., such as the inventive selective precharge skipping) can be used to further lower dynamic power consumption, addressing challenges like read disturb failures during write-masked operations. Hence, a scalable, power-efficient solution for modern computing systems can be achieved.

The global bitline precharge signal (GBLPRECH) is a timing signal used to trigger the precharge operation for all bitlines on the full bus. It activates the circuitry responsible for precharging the bitlines to a defined voltage level, ensuring readiness for any memory operation, whether read, write, or read-write. The local bitline precharge signal (NBLPRECH) enables selective precharge operations for specific bitlines or subsets of the bus within a memory array. It provides localized control, allowing targeted bitlines to be precharged to a defined voltage level, optimizing power and performance by limiting precharge activity to the necessary regions during read, write, or read-write operations. WE_LAT is a control signal for individual bits in a memory array, derived as the inverted output of a latched write enable (WEN) signal. It enables localized control, allowing some bits to undergo write operation, while others may not, supporting fine-grained write operation control.

A local sense amplifier precharge signal (NSAPRECH)” is the output of a NAND gate that combines an inverted sense amplifier enable signal (inverted SAE) and a global sense amplifier precharge signal (SAPRECH), where such NSAPRECH corresponds to the precharge phase of a read operation in single-port memory. This signal is fed into circuitry that integrates it with a latched control signal (WE_LAT) and a global bitline precharge signal (GBLPRECH) to generate a selective local precharge signal (NBLPRECH), enabling precise timing and control of precharge operations for specific bitcells. The global timing pulse signal (GTP) is an internally generated clock signal that provides a uniform time reference for read and write memory operations across the chip, ensuring synchronized and coherent functionality during both functional and test modes.

The clock signal (CLK) is a periodic timing signal used to synchronize operations across a circuit, providing a reference for the sequential execution of tasks such as data transfers, computations, and control signal generation in digital systems. A global write enable signal (GWEN) is a binary control signal used in circuit design to determine whether a write operation should occur for an entire word or memory location. GWEN operates at the word or block level, enabling or disabling the writing of data to the addressed memory cell or register. For example, if GWEN is active, the entire word is updated based on the input data; otherwise, the write operation is suppressed. Write mask (WEN[n]) is a multi-bit signal that specifies which individual bits within a word should be written during a write operation. Each bit of the write mask corresponds to a bit in the data word, with an active bit allowing the corresponding data bit to be written and an inactive bit leaving the original value unchanged. This enables selective bit-level updates within a word, providing more granularity than a write enable signal alone.

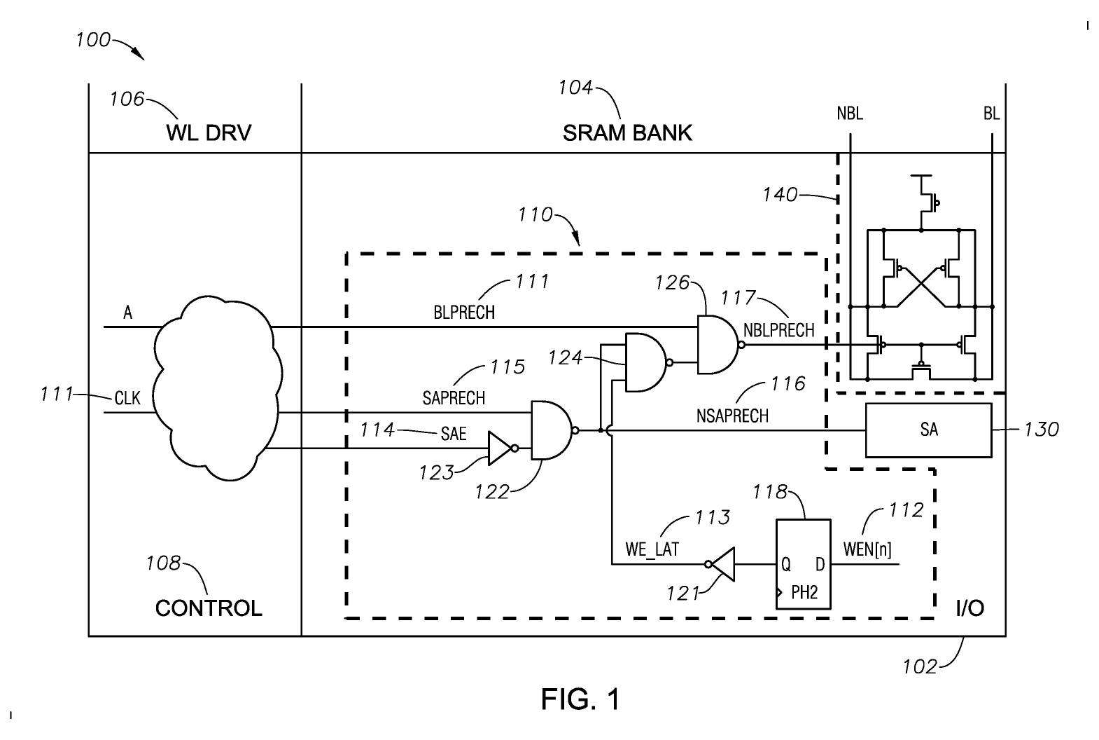

Referring to FIG. 1, an example circuit arrangement 100 (e.g., a pseudo-two port (p-2P Execution Engine-General Purpose Register File (EE-GPRF) graphics processing unit (GPU) memory) according to example implementations is shown. As illustrated, the circuit arrangement 100 may include I/O output circuitry (e.g., I/O) 102, one or more bitcell memory banks (e.g., SRAM bank) 104, wordline driver circuitry (e.g., WL DRV) 106, and control circuitry (e.g., CONTROL) 108. In various implementations, as shown, the I/O circuitry 102 may include inventive precharge control circuitry 110, a sense amplifier (e.g., SA) 130, and bitline circuitry 140.

In various aspects, the precharge control circuitry 110 includes first and second logic gates 124, 126 (e.g., NAND gates). In certain implementations, the first logic gate 124 is configured to output a local bitline precharge signal (NBLPRECH) 117 based on a global bitline precharge signal (GBLPRECH) 111 and an output of the second logic gate 126. Also, for example, the output of the second logic gate 126 is based on at least a local sense amplifier precharge signal (NSAPRECH) 116 and a control signal 113 (e.g., an inverted write enable latch signal, WE_LAT). Moreover, the circuit 110 is configured to selectively control a precharge of one or more bitcells (e.g., bitline circuitry 140; one or more bitcell memory banks 104) based on enabling or disabling the local bitline precharge signal (NBLPRECH) 117. In some implementations, the local bitline precharge signal (NBLPRECH) 117 is based on at least the control signal 113 (e.g., an inverted write enable latch signal (WE_LAT)), the global bitline precharge signal (GBLPRECH) 111, and the local sense amplifier precharge signal (NSAPRECH) 116.

In certain implementations, the precharge control circuitry 110 includes a latch 118, and a first inverter 121. For example, the latch 118 is configured to output a latched write enable signal based on a write enable signal, (WEN[n]). Also, the first inverter 121 is configured to output the control signal (e.g., an inverted write enable latch signal (WE_LAT)) 113 based on the latched write enable signal (WEN[n]). In addition, the first inverter 121 may be coupled between the latch 118 and the second logic gate (e.g., 2nd NAND gate) 124, such that the control signal 113 is a first input to the second logic gate 124. In some cases, the precharge control circuitry 110 includes a third logic gate (e.g., a third NAND gate) 122. For example, the third logic gate 122 may output the local sense amplifier precharge signal (NSAPRECH) 116 based on an inverted sense amplifier enable signal (i.e., the output of a second inverter 123 that is configured to receive the sense amplifier enable signal (SAE) 114) and a global sense amplifier precharge signal (SAPRECH) 115. Additionally, in certain instances, the first logic gate 126 is configured to receive the global precharge signal (GBLPRECH) 111 and the output of the second logic gate 124. Also, the second logic gate 124 can be configured to receive the local sense amplifier precharge signal (NSAPRECH) 116 and the control signal (WE_LAT) 113.

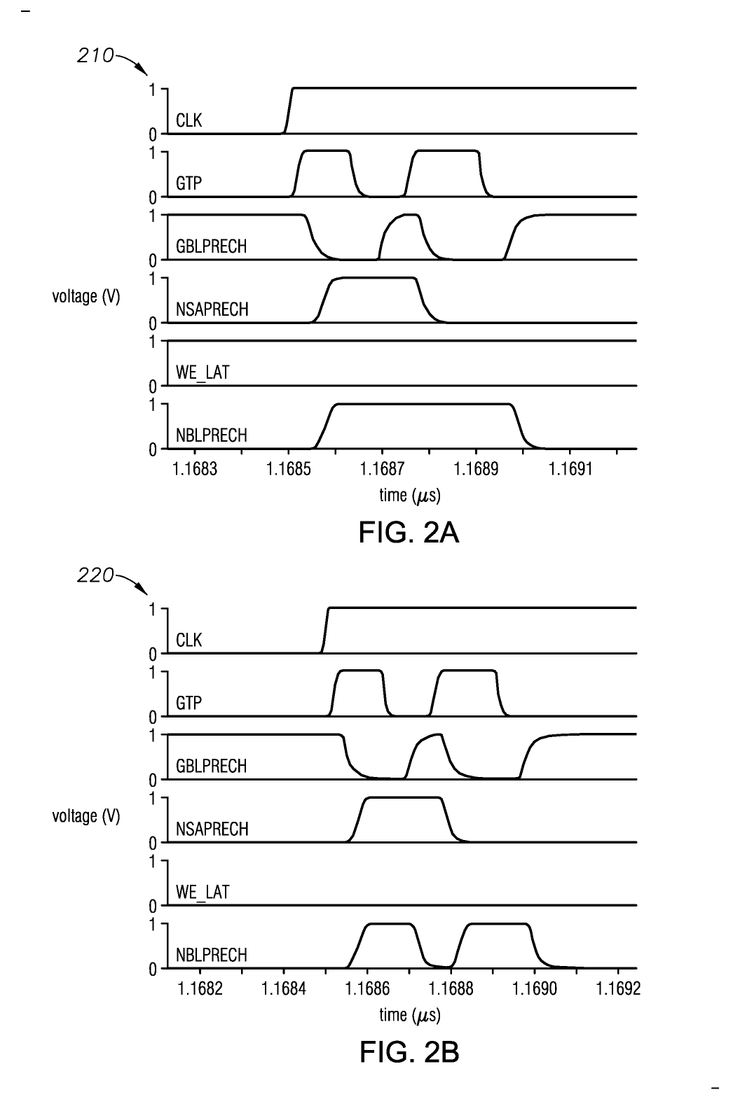

As described with reference to example operations, the circuit 100 can be configured for read-write cycle (RDWR cycle) operations. In a first example, when a write mask is inactive (e.g., WEN[n]=0, as shown in FIG. 2A below), the local bitline precharge signal (NBLPRCH) 117 would be asserted to a digital high state (“1”) for a duration of both a read operation and a write operation. In such an example, the digital high state of the local bitline precharge signal (NBLPRCH) 117 would correspond to the disabled bitline precharge signal (after a first GTP pulse, for example, as illustrated in FIG. 2A). In a second example, when a write mask is active (WEN[n]=1, as shown in FIG. 2B below), the local bitline precharge signal (NBLPRCH) is asserted to a digital low state (“0”) for a duration between a read operation and a write operation. For instance, in such a second example, the digital low state of the local bitline precharge signal (NBLPRCH) 117 would correspond to the enabled bitline precharge signal (e.g., a “dip” between two separate GTP pulses).

As described with reference to example operations, the circuit 100 can be also configured for just a read cycle (e.g., RD-only cycle) operation or just a write cycle (e.g., WR-only cycle) operation. For instance, for a read cycle (e.g., RD-only cycle), the local bitline precharge signal (NBLPRCH) 117 can be asserted to a digital high state (“1”) for a duration corresponding to a read operation (e.g., following a GTP pulse, upon detection of NSAPRECH 116). In addition, for such an example, the digital high state of the local bitline precharge signal (NBLPRCH) 117 would correspond to the enabled bitline precharge signal. For instance for a write cycle (e.g., WR-only cycle), the bitline precharge signal (NBLPRCH) 117 can be asserted to a digital high state (“1”) for a duration corresponding to a write operation (e.g., following a delayed GTP pulse, and upon no detection of NSAPRECH 117 and a detection of WE_LAT 113). In addition, for such an example, the digital high state of the bitline precharge signal (NBLPRCH) 117 would correspond to the enabled bitline precharge signal.

In certain implementations, as illustrated in FIG. 1, the circuit 100 corresponds to a memory macro unit (e.g., single port (SRAM) memory; a single port with “double-pump” memory/ internal two-GTP clock pulses (e.g., read and write), GPU or central processing unit (CPU)). As shown, the precharge control circuitry 110 can be located within the input/output (I/O) circuitry 102 of the memory macro unit 100.

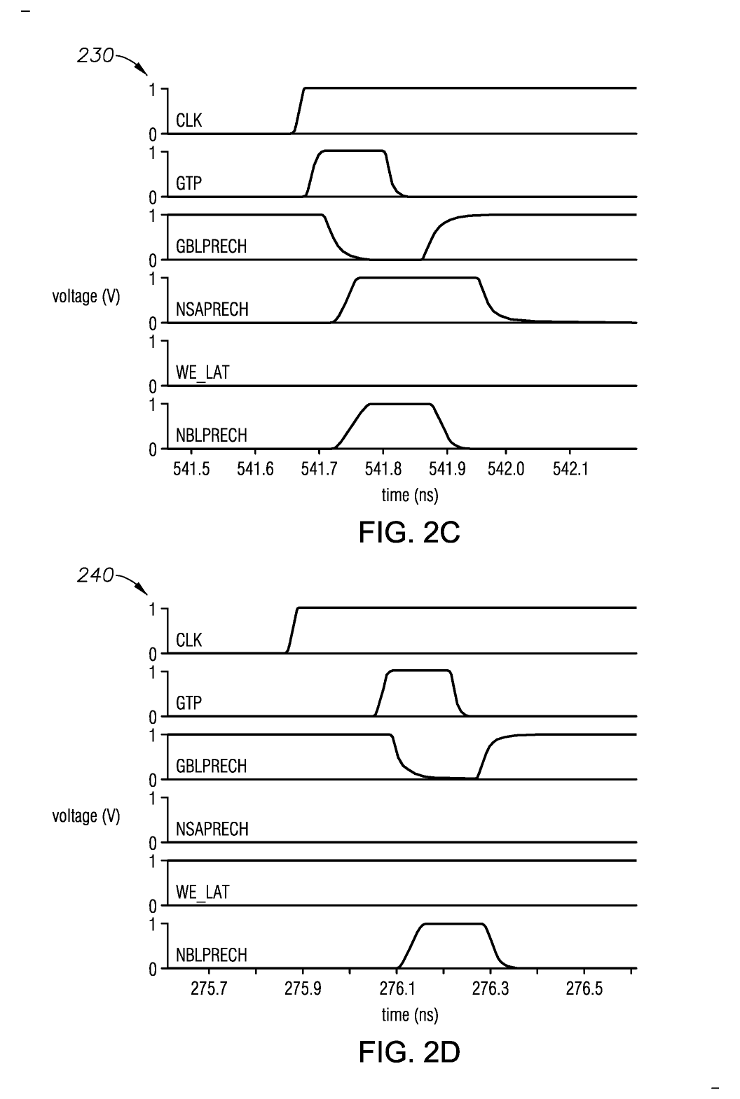

Referring to FIGS. 2A-2D, example waveform timing diagrams 210, 220, 230, and 240 are discussed with reference to the inventive precharge control circuitry 110 in FIG. 1 according to example implementations. Each of the timing diagrams FIGS. 2A-2D illustrate voltage (V) (e.g., from digital high (“1”) to digital low (“0”)) as a function of time (e.g., μs, ns) for the following signal waveforms: CLK, GTP, GBLPRECH, NSAPRECH, WE_LAT, and NBLPRECH. As one example, FIG. 1A illustrates the timing diagram for each of such signal waveforms during a read-write cycle (RDWR cycle) operation when write mask is inactive (i.e., “OFF”) (e.g., WEN[n] = 0). Likewise, FIG. 2B illustrates the timing diagram for each of such signal waveforms during a read-write cycle (RDWR cycle) operation when write mask is active (i.e., “ON”) (e.g., WEN[n] = 1). In addition, FIG. 2C illustrates the timing diagram for each of such signal waveforms during a read cycle (e.g., RD-only cycle) operation, while FIG. 2D illustrates the timing diagram for each of such signal waveforms during a write cycle (e.g., WR-only cycle) operation. Each of the above-mentioned operations will be explained in greater detail with reference to the operational system flowchart illustrated in FIG. 3.

FIG. 3 is an example flow diagram 300 is shown in accordance with certain implementations. As illustrated, the flow diagram 300 represents an example order of system operation. In various implementations, an inventive system (e.g., inventive scheme involving the circuit 100 implemented in accordance with example computer 600) provides the capacity to control selective bitline precharge. For instance, the system has the capability to enact bitline precharging at the optimal time.

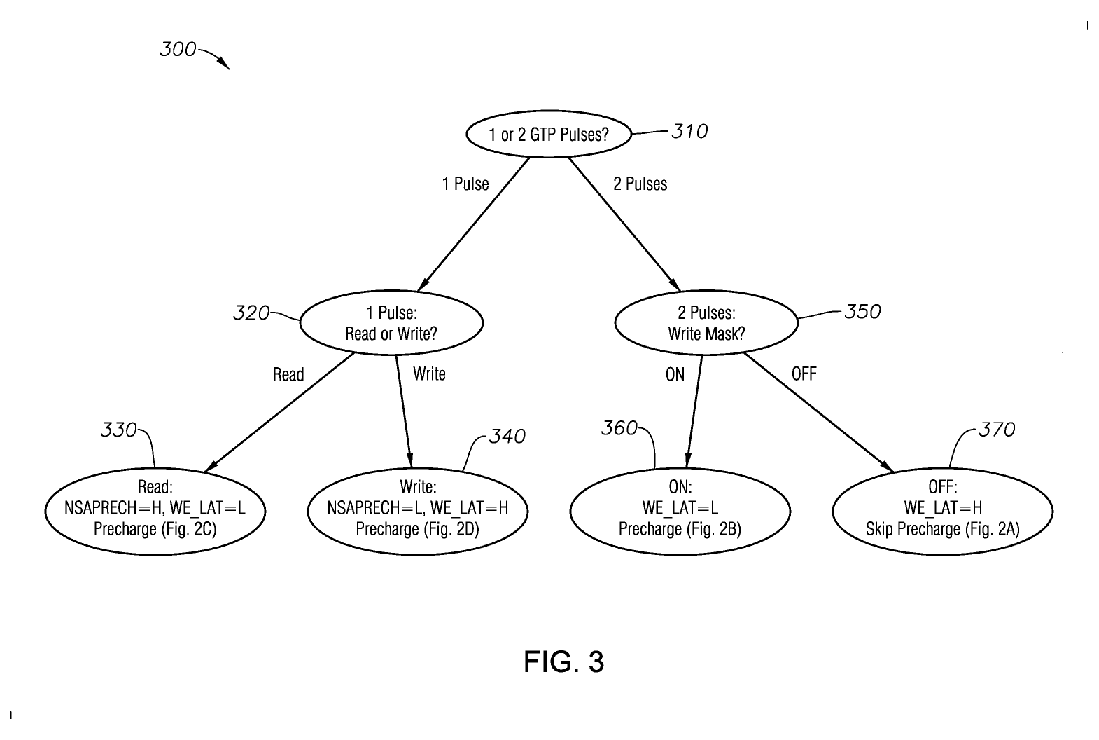

At Step 310, the system detects whether one or two GTP pulses are transmitted per clock cycle (see also FIG. 4). If it is determined that one GTP pulse is received per clock cycle, the system moves to Step 320 where the system detects the whether the one GTP pulse corresponds to either a read operation or a write operation. For example, if it is determined that the GTP pulse corresponds to a read-only operation, the system moves to Step 330, and follows the FIG. 2C timing diagram. At Step 330, as shown in FIG. 2C, upon the transition to the one GTP pulse to a digital high state (e.g., “H”; a digital “1”), the NSAPRECH is asserted to a digital high state and the WE_LAT to a digital low state, whereby such assertions indicating that they cycle is a read-only operation. Upon doing so, the local bitline precharge is enabled (e.g., NBLPRECH to a digital high state) subsequent to the initialization of the read operation (as indicated by the transition of the GTP pulse). In contrast, for example, if it is determined that the GTP pulse corresponds to a write-only operation, the system operates to Step 340 following the FIG. 2D timing diagram. At Step 340, as shown in FIG. 2D, upon the transition of the one GTP pulse to a digital high state (e.g., “H”; a digital “1”), the NSAPRECH is asserted to a digital low state and the WE_LAT to a digital high state, whereby such assertions indicating that they cycle is a write-only operation. Upon doing so, the local bitline precharge is enabled (e.g., NBLPRECH to a digital high state) subsequent to the initialization of the write operation (as indicated by the transition of the GTP pulse).

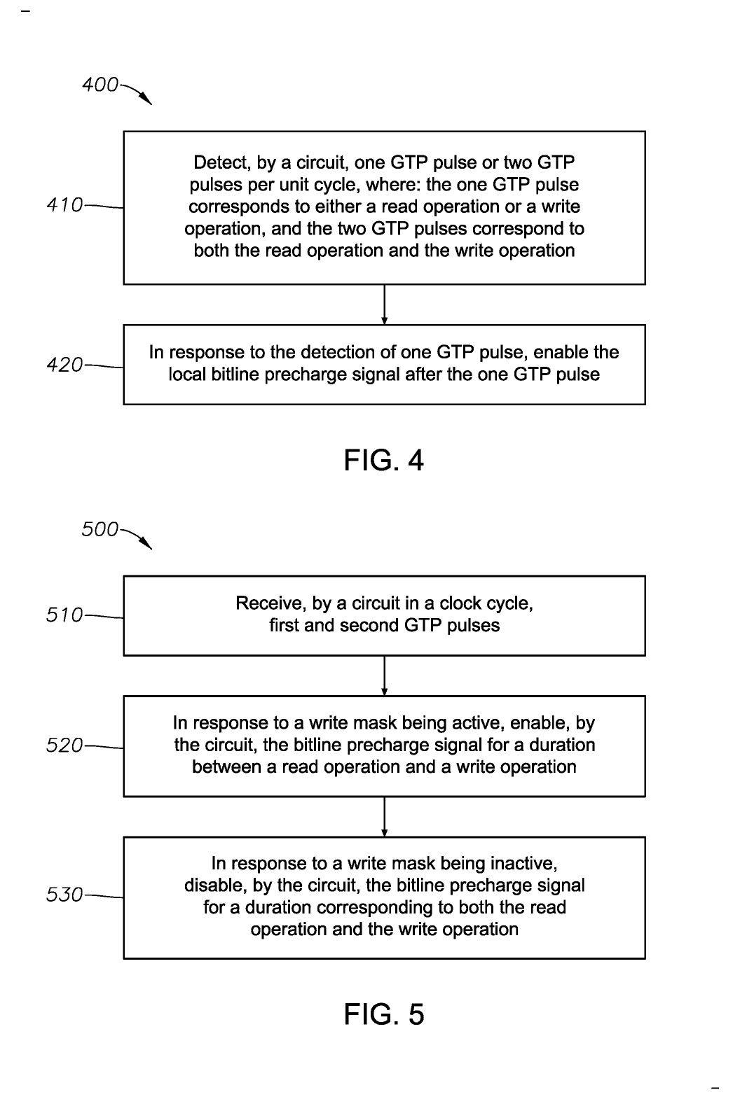

In contrast, at Step 310, if it is determined that two GTP pulses are received per clock cycle, the system operates to Step 350. At Step 350, the system detects whether the write mask (e.g., WEN[n]) is “ON” (e.g., active, enabled) or “OFF” (see also FIG. 5). For example, if it is determined that the write mask is active (e.g., WEN asserted at a digital high state (e.g., “H”; a digital “1”), and correspondingly, WE_LAT asserted at a digital low state (e.g., “L”, a digital “0”)), the local bitline precharge is enabled (e.g., NBLPRECH asserted at a digital low state) for a duration between a read operation and a write operation (e.g., as shown by the “dip” in NBLPRECH in FIG. 2B, e.g., the transition from “1” to “0” and back to “1” following a somewhat similar dip of the GTP pulses distinguishing the read and write operations). In contrast, for example, if it is determined that the write mask is inactive (e.g. WEN asserted as a digital low state, and correspondingly, WE_LAT asserted as a digital high state (“H”)), the local bitline precharge signal is selectively disabled (e.g., NBLPRCH asserted at a digital high state in FIG. 2A) for a duration corresponding to both the read operation and the write operation. Accordingly, the system selectively ‘skips’ the first BL precharge after a first GTP pulse (e.g., a read operation) to save dynamic power).

Referring to FIG. 4, a flowchart of an example operational method 400 (i.e., procedure) is shown. Advantageously, in various implementations, the method 400 describes the capability for selective bitline precharge. The method 400 may be implemented with reference to implementation as shown with reference to FIGS. 1-3.

At block 410, the example method 400 includes: detecting, by a circuit, one GTP pulse or twoGTP pulses per unit cycle, wherein: the one GTP pulse corresponds to either a read operation or a write operation, and the two GTP pulses correspond to both the read operation and the write operation. For instance, as described with reference to FIGS. 1-3, the circuit 100 (in conjunction with the computer 600) is configured to detect one GTP pulse or two GTP pulses per unit cycle.

At block 420, the example method 400 includes: in response to the detection of one GTP pulse, enabling the bitline precharge signal after the one GTP pulse. For instance, as described with reference to FIGS. 1-3, in response to the detection of one GTP pulse, enabling (turn on) the local bitline precharge signal (NBLPRCH) after the one GTP pulse (e.g., for both RD-only (FIG. 2C) and WR-only scenarios (FIG. 2D)).

In certain cases, the method 400 further includes: determining the read operation (FIG. 2C) based on a (local) sense amplifier precharge signal asserting a digital high state (“1”) (and a control signal (WE_LAT) asserting a digital low state (“0”)). In other cases, the method 400 further includes: determining the write operation (FIG. 2D) based on a mixed sense amplifier precharge signal asserting a digital low state (“0”) and a control signal (WE_LAT) asserting a digital high state (“1”) (e.g., in such a scenario, the GTP pulse may delayed, and so, NBLPRECH would in turn be delayed).

In some implementations, the method 400 includes: in response to a detection of the two GTP pulses, detecting if a write mask is active (WEN=1; FIG. 2B). Moreover, in response to the write mask being active (WEN=1, WE_LAT=0, FIG. 2B), enabling the local bitline precharge signal (NBLPRCH=0) for a duration between a read operation and a write operation (as corresponding to the two GTP pulses). In addition, in response to the write mask being inactive (WEN=0, WE_LAT=1, FIG. 2A), disabling the local bitline precharge signal (NBLPRCH=1) for a duration corresponding to both the read operation and the write operation (so, e.g., the first BL precharge after a first GTP pulse is skipped to save dynamic power).

Referring to FIG. 5, a flowchart of an example operational method 500 (i.e., procedure) is shown. Advantageously, in various implementations, the method 500 describes the capability to reduce dynamic power for read-write (RD-WR) cycles. The method 500 may be implemented with reference to implementation as shown with reference to FIGS. 1, 2A-2B, and 3.

At block 510, the example method 500 includes: receiving, by a circuit in a clock cycle, first and second GTP pulses. For instance, as described with reference to FIGS. 1, 2A-2B and 3, the circuit 100 is configured to receive first and second GTP pulses in one clock cycle.

At block 520, the example method 500 includes: in response to a write mask being active, enabling, by the circuit, the bitline precharge signal for a duration between a read operation and a write operation. For instance, as described with reference to FIGS. 1, 2B, and 3, in response to a write mask being active (WEN=1, WE_LAT=0, FIG. 2B), enabling, by the circuit 100, the local bitline precharge signal (NBLPRCH=0) for a duration between a read operation and a write operation (e.g., “the dip” in NBLPRECH).

At block 530, the example method 500 includes: in response to a write mask being inactive, disabling, by the circuit, the bitline precharge signal (NBLPRCH=1) for a duration corresponding to both the read operation and the write operation. For instance, as described with reference to FIGS. 1, 2A, and 3, in response to a write mask being inactive (WEN=0, WE_LAT=1, FIG. 2A), disabling, by the circuit 100, the bitline precharge signal (NBLPRCH=1) for a duration corresponding to both the read operation and the write operation (so, e.g., the first BL precharge after a first GTP pulse is skipped to save dynamic power). In certain implementations, the method 500 includes the first GTP pulse corresponding to a read operation, and the second GTP pulse corresponding to a write operation.

In some cases, the method 500 includes where that the local bitline precharge signal (NBLPRCH) is enabled (e.g., FIG. 2B) when: a global precharge signal (GBLPRECH) transitions to a digital high state (“1”) in between the first and second GTP pulses, a mixed sense amplifier precharge signal (NSAPRECH) is asserted to a digital high state (“1”), and a control signal (WE_LAT) is asserted to a digital low state (“0”). In other cases, the method 500 includes that the local bitline precharge signal (NBLPRCH) is disabled (FIG. 2A) when: a global precharge signal (GBLPRECH) transitions to a digital high state (“1”) in between the first and second GTP pulses, a mixed sense amplifier precharge signal (NSAPRECH) is asserted to a digital high state (“1”), and a control signal (WE_LAT) is asserted to a digital high state (“1”).

In certain implementations, the method 500 includes where the disabling, by the circuit 100, of the local bitline precharge signal (NSAPRECH) for a duration corresponding to both the read operation and the write operation corresponds to a selective skip of a bitline precharge after the read operation (e.g., to save dynamic power).

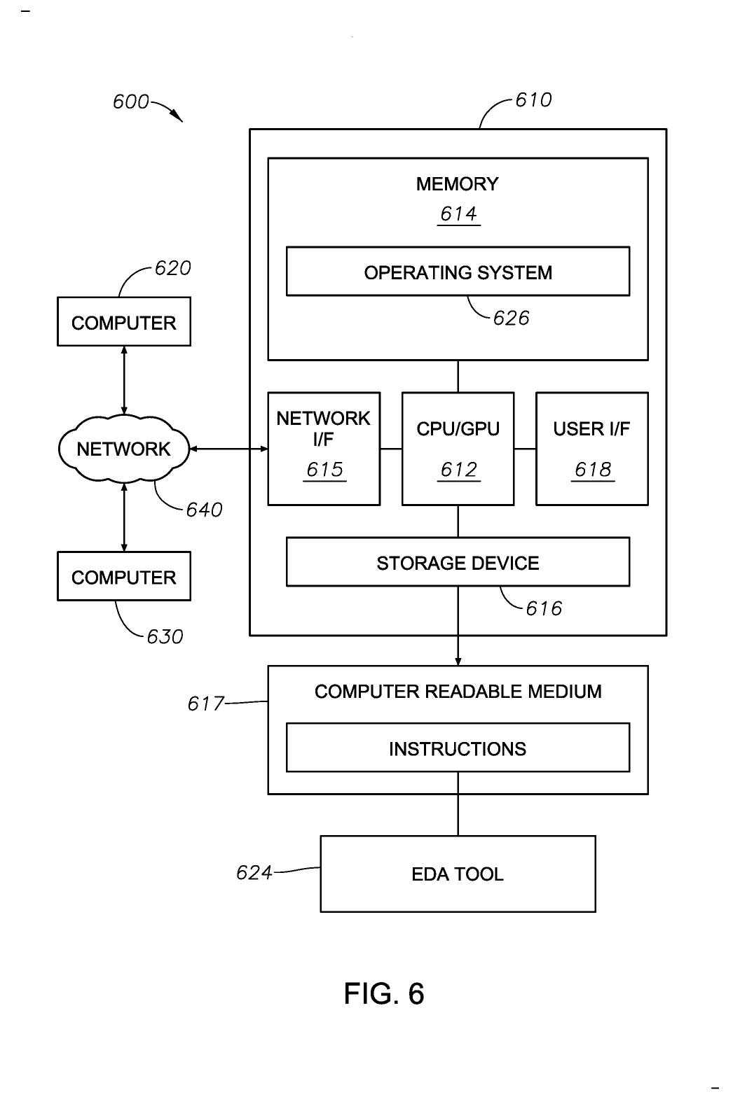

FIG. 6 illustrates example hardware components in the computer system 600 that may be used to facilitate and generate the inventive circuit design/memory architecture output. In certain implementations, the example computer system 600 (e.g., networked computer system and/or server) may include EDA tool 624 to execute software based on the procedure as described with reference to the methods as described herein. For example, FIG. 6 illustrates example hardware components in the computer system 600 that may be used to selectively control when the bitline precharge signal (NBLPRCH) is enabled or disabled. In certain implementations, the EDA too 624 may be included as a feature of an existing compiler software program. In certain implementations, an EDA (Electronic Design Automation) tool 624 would automate signal detection and control logic configuration for the schemes and techniques as described herein (e.g., with reference to the circuit 100 illustrated in FIG. 1 and the flow diagram 300 illustrated in FIG. 3).

For instance, the EDA tool 624 is configured to enact the inventive circuit design by automating the synthesis, simulation, verification, and optimization of the memory control logic to implement the described functionality. The tool 624 begins by incorporating logic to detect the number of GTP pulses (one or two) and interpreting runtime signals such as NSAPRECH, WE_LAT, and the write mask state. As one example, this detection forms the basis for conditional precharge control, enabling or skipping bit-line precharge dynamically depending on the operation type and write mask conditions. In certain instances, the EDA tool 624 also synthesizes custom circuit modules to implement the conditional logic, including precharge control blocks, signal processing units, and waveform synchronization elements, ensuring alignment with the memory’s clock cycle and operational timing. Functional simulation verifies the design across different scenarios, such as distinguishing between read-only and write-only operations for a single GTP pulse or handling the write mask ON/OFF cases for two pulses, validating both functionality and power-saving capabilities.

In addition, the EDA tool 624 performs critical path analysis and timing optimization to ensure fast GTP pulse detection and reliable signal transitions, minimizing delays while maintaining data integrity. As may be appreciated, for example, physical design steps can focus on layout optimization to reduce area and routing overhead while isolating sensitive signals like NBLPRECH to prevent interference. Also, power analysis can quantify the dynamic power reduction achieved through selective precharge skipping, ensuring compliance with power, performance, and area (PPA) goals. Further, formal verification can confirm the design's equivalence to the specification, where test vectors are generated for post-silicon validation. Moreover, the finalized design can be integrated into the larger GPU or system-on-chip (SoC) architecture, with runtime tunability for dynamic workload adjustments. Hence, advantageously, such a comprehensive example workflow enables efficient and scalable implementation of the inventive memory architecture, balancing performance and power efficiency for high-performance computing systems.

The procedures (e.g., 400, 500), for example, may be stored as program instructions as instructions 617 in the computer readable medium of the storage device 616 (or alternatively, in memory 614) that may be executed by the computer 610, or networked computers 620, 630, other networked electronic devices (not shown) or a combination thereof. In certain implementations, each of the computers 610, 620, 630 may be any type of computer, computer system, or other programmable electronic device. Further, each of the computers 610, 620, 630 may be implemented using one or more networked computers, e.g., in a cluster or other distributed computing system.

In certain implementations, the system 600 may be used with semiconductor integrated circuit (IC) designs that contain all standard cells, all blocks or a mixture of standard cells and blocks. In a particular example implementation, the system 600 may include in its database structures: a collection of cell libraries, one or more technology files, a plurality of cell library format files, a set of top design format files, one or more Open Artwork System Interchange Standard (OASIS/ OASIS.MASK) files, and/or at least one EDIF file. The database of the system 600 may be stored in one or more of memory 614 or storage devices 616 of computer 610 or in networked computers 620, 630.

In one implementation, the computer 600 includes a central processing unit (CPU) 612 (or graphics processing unit (GPU) or neural processing unit (NPU) in certain implementations) having at least one hardware-based processor coupled to a memory 614. The memory 614 may represent random access memory (RAM) devices of main storage of the computer 610, supplemental levels of memory (e.g., cache memories, non-volatile or backup memories (e.g., programmable or flash memories)), read-only memories, or combinations thereof. In addition to the memory 614, the computer system 600 may include other memory located elsewhere in the computer 610, such as cache memory in the CPU 612, as well as any storage capacity used as a virtual memory (e.g., as stored on a storage device 616 or on another computer coupled to the computer 610).

The computer 610 may further be configured to communicate information externally. To interface with a user or operator (e.g., a circuit design engineer), the computer 610 may include a user interface (I/F) 618 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 610 may include a network interface (I/F) 615 which may be coupled to one or more networks 640 (e.g., a wireless network) to enable communication of information with other computers and electronic devices. The computer 560 may include analog and/or digital interfaces between the CPU 612 and each of the components 614, 615, 616, and 618. Further, other non-limiting hardware environments may be used within the context of example implementations.

The computer 610 may operate under the control of an operating system 626 and may execute or otherwise rely upon various computer software applications, components, programs, objects, modules, data structures, etc. (such as the programs associated with the procedure 400 and related software). The operating system 628 may be stored in the memory 614. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 626 in the example of FIG. 6 is shown in the memory 614, but components of the aforementioned software may also, or in addition, be stored at non-volatile memory (e.g., on storage device 616) and/or the non-volatile memory (not shown). Moreover, various applications, components, programs, objects, modules, etc. may also execute on one or more processors in another computer coupled to the computer 610 via the network 640 (e.g., in a distributed or client-server computing environment) where the processing to implement the functions of a computer program may be allocated to multiple computers 620, 630 over the network 640. In example implementations, circuit related diagrams have been provided in FIG. 1-6, whose redundant description has not been duplicated in the related description of analogous circuit related diagrams. It is expressly incorporated that the same diagrams with identical symbols and/or reference numerals are included in each of embodiments based on its corresponding figure(s).

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user’s computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, where such instructions may execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit for selective bitline precharge, comprising:
first and second logic gates, wherein:
the first logic gate is configured to output a bitline precharge signal based on a global bitline precharge signal and an output of the second logic gate; and
the output of the second logic gate is based on at least a sense amplifier precharge signal and a control signal; and wherein:
the circuit is configured to control a precharge of one or more bitcells based on enabling or disabling the bitline precharge signal.

2. The circuit of claim 1, wherein the bitline precharge signal is based on at least the control signal, the global bitline precharge signal, and the sense amplifier precharge signal.

3. The circuit of claim 1, further comprising:
a latch, and
a first inverter, wherein:
the latch is configured to output a latched write enable signal based on a write enable signal; and
the first inverter is configured to output the control signal based on the latched write enable signal, wherein the first inverter is coupled between the latch and the second logic gate.

4. The circuit of claim 1, wherein:
in a single clock cycle, the circuit is configured to receive either one or two global timing pulse signal (GTP) pulses;
the one GTP pulse corresponds to either a read operation or a write operation and the two GTP pulses correspond to both the read operation and the write operation; and
each of the one or the two GTP pulses corresponds to an internally generated clock signal configured to provide a uniform time reference for memory operations.

5. The circuit of claim 1, further comprising:
a third logic gate that outputs the sense amplifier precharge signal based on an inverted sense amplifier enable signal and a global sense amplifier precharge signal.

6. The circuit of claim 1, wherein:
the first logic gate is configured to receive the global precharge signal and the output of the second logic gate; and
the second logic gate is configured to receive the sense amplifier precharge signal and the control signal.

7. The circuit of claim 1, wherein:
for a read-write cycle, when a write mask is inactive, the bitline precharge signalis asserted to a digital high state for a duration of both a read operation and a write operation; and
the digital high state of the bitline precharge signal corresponds to the disabled bitline precharge signal.

8. The circuit of claim 1, wherein:
for a read-write cycle, when a write mask is active, the bitline precharge signalis asserted to a digital low state for a duration between a read operation and a write operation; and
the digital low state of the bitline precharge signal corresponds to the enabled bitline precharge signal.

9. The circuit of claim 1, wherein:
for a read cycle, the bitline precharge signal is asserted to a digital high state for a duration corresponding to a read operation; and
the digital high state of the bitline precharge signal corresponds to the enabled bitline precharge signal.

10. The circuit of claim 1, wherein:
for a write cycle, the bitline precharge signal is asserted to a digital high state for a duration corresponding to a write operation; and
the digital high state of the bitline precharge signal corresponds to the enabled bitline precharge signal.

11. The circuit of claim 1, wherein:
the circuit is comprised within a memory macro unit; and
the circuit is located in input/output (I/O) circuitry of the memory macro unit.

12. A method for selective bitline precharge, comprising:
detecting, by a circuit, one GTP pulse or two GTP pulses per unit cycle, wherein:
the one GTP pulse corresponds to either a read operation or a write operation, and
the two GTP pulses correspond to both the read operation and the write operation; and
in response to the detection of one GTP pulse, enablingthe bitline precharge signal after the one GTP pulse.

13. The method of claim 12, wherein:
each of the one GTP pulse or the two GTP pulses corresponds to an internally generated clock signal configured to provide a uniform time reference for memory operations, and further comprising:
determining the read operation based on a sense amplifier precharge signal asserting a digital high state.

14. The method of claim 12, further comprising:
determining the write operation based on a mixed sense amplifier precharge signal asserting a digital low state and a control signal asserting a digital high state.

15. The method of claim 12, further comprising:
in response to a detection of the two GTP pulses, detecting if a write mask is active;
in response to the write mask being active, enabling the bitline precharge signal for a duration between a read operation and a write operation; and
in response to the write mask being inactive, disabling the bitline precharge signal for a duration corresponding to both the read operation and the write operation.

16. A method for selective bitline precharge, comprising:
receiving, by a circuit in a clock cycle, first and second GTP pulses;
in response to a write mask being active, enabling, by the circuit, the bitline precharge signal for a duration between a read operation and a write operation; and
in response to a write mask being inactive, disabling, by the circuit, the bitline precharge signal for a duration corresponding to both the read operation and the write operation.

17. The method of claim 16, wherein:
the first GTP pulse corresponds to a read operation;
the second GTP pulse corresponds to a write operation; and
each of the first GTP pulse or the second GTP pulse corresponds to an internally generated clock signal configured to provide a uniform time reference for memory operations.

18. The method of claim 16, wherein the bitline precharge signal is enabled when:
a global precharge signal transitions to a digital high state in between the first and second GTP pulses,
a mixed sense amplifier precharge signal is asserted to a digital high state, and
a control signal is asserted to a digital low state.

19. The method of claim 16, wherein the bitline precharge signal is disabled when:
a global precharge signaltransitions to a digital high state in between the first and second GTP pulses,
a mixed sense amplifier precharge signal is asserted to a digital high state, and
a control signal is asserted to a digital high state.

20. The method of claim 16, wherein:
the disabling, by the circuit, the bitline precharge signal for a duration corresponding to both the read operation and the write operation corresponds to a selective skip of a bitline precharge after the read operation.
